(19) United States
(12) Patent Application Publication
(10) Pub. No.: US 2025/0370325 A1
(43) Pub. Date: Dec. 4, 2025

(54) EUV LITHOGRAPHY MASKS AND METHODS

(71) Applicant: Taiwan Semiconductor Manufacturing Co., Ltd., Hsinchu (TW)

(72) Inventors: Lee-Feng CHEN, Hsinchu (TW); Yen-Liang CHEN, Hsinchu (TW); Chien-Min LEE, Hsinchu (TW); Kuo Lun TAI, Hsinchu (TW); Shy-Jay LIN, Hsinchu (TW)

(73) Assignee: Taiwan Semiconductor Manufacturing Co., Ltd., Hsinchu (TW)

(21) Appl. No.: 19/294,085

(22) Filed: Aug. 7, 2025

Related U.S. Application Data
(63) Continuation of application No. 18/434,528, filed on Feb. 6, 2024.
(60) Provisional application No. 63/583,466, filed on Sep. 18, 2023.

(51) Int. Cl. G03F 1/24

(52) U.S. Cl. CPC G03F 1/24

(57) ABSTRACT

An EUV lithography mask including a substrate, a patterned absorber layer including a first material and a second material. In some embodiments, the first material is a second row transition metal and the second material is a first row transition metal or second row transition metal. The disclosed EUV lithography masks reduce undesirable mask 3D effects.

### PRIORITY CLAIM AND CROSS-REFERENCE

This application is a Continuation of U.S. application Ser. No. 18/434,528, filed Feb. 6, 2024, which claims the benefit of U.S. Provisional Patent Application No. 63/583,466, filed Sep. 18, 2023, each of which is incorporated by reference herein in its entirety.

### BACKGROUND

The semiconductor industry has experienced exponential growth. Technological advances in materials and design have produced generations of integrated circuits (ICs), where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

Photolithography utilizing extreme ultraviolet radiation (EUV) is useful for achieving increased functional density. EUV photolithography utilizes a mask to produce patterns of reflected EUV radiation which is used to expose photosensitive materials such as photoresists.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an extreme ultraviolet (EUV) mask blank, in accordance with some embodiments.

FIG. 2 is a flowchart of a method for fabricating the EUV mask blank of FIG. 1, in accordance with some embodiments.

FIGS. 3A-3D are cross-sectional views of an EUV mask blank at various stages of the fabrication process of FIG. 2, in accordance with some embodiments.

FIGS. 3E-3G are cross-sectional views of embodiments of an EUV mask blank with different embodiments of an absorber layer configured in accordance with the present disclosure.

FIG. 4 is a cross-sectional view of an EUV mask, in accordance with some embodiments.

FIG. 5 is a flowchart of a method for fabricating the EUV mask of FIG. 4, in accordance with some embodiments.

FIGS. 6A-6G are cross-sectional views of an EUV mask at various stages of the fabrication process of FIG. 5, in accordance with some embodiments.

FIG. 7 is a schematic diagram of a lithography system, in accordance with some embodiments of the present disclosure.

FIG. 8 is a flowchart of a method of using an EUV mask, in accordance with embodiments of the present disclosure.

FIG. 9 depicts a “green zone” for use in identifying combinations of first and second materials for use in an absorber layer of EUV masks blanks and masks of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the manufacture of integrated circuits (ICs), patterns representing different layers of the ICs are fabricated using a series of reusable photomasks (also referred to herein as photolithography masks or masks). The photomasks are used to transfer the design of each layer of the ICs onto a semiconductor substrate during the semiconductor device fabrication process.

With the shrinkage in IC size, various types of this lithography techniques such as immersion lithography utilizing wavelengths on the order of 193 nm from an ArF laser or extreme ultraviolet (EUV) light with a wavelength of 13.5 nm is employed in, for example, a lithographic process to enable transfer of very small patterns (e.g., nanometer-scale patterns) from a mask to a semiconductor wafer.

An ongoing desire to have more densely packed integrated devices has resulted in changes to the photolithography process in order to form smaller individual feature sizes. The minimum feature size or “critical dimension” (CD) obtainable by a process is determined approximately by the formula CD=K₁*λ/NA, where k₁ is a process-specific coefficient, λ is the wavelength of applied light/energy, and NA is the numerical aperture of the optical lens as seen from the substrate or wafer.

For fabrication of dense features with a given value of k₁, the ability to project a usable image of a small feature onto a wafer is limited by the wavelength λ and the ability of the projection optics to capture enough diffraction orders from an illuminated mask. When either dense features or isolated features are made from a photomask or a reticle of a certain size and/or shape, the transitions between light and dark at the edges of the projected image may not be sufficiently sharply defined to correctly form target photoresist patterns. As a result, features 150 nm or below in size may need to utilize phase shifting masks (PSMs) or techniques to enhance the image quality at the wafer, e.g., sharpening edges of features to improve resist profiles.

Phase-shifting generally involves selectively changing phases of part of the energy passing through a photomask/reticle so that the phase-shifted energy is additive or subtractive with energy that is not phase-shifted at the surface of the material on the wafer that is to be exposed and patterned. By carefully controlling the shape, location, and phase shift angle of mask features, the resulting photoresist patterns can have more precisely defined edges. As the feature size reduces, an imbalance of transmission intensity between the 0° and 180° phase portions and a phase shift that varies from 180° can result in significant critical dimension (CD) variation and placement errors for the photoresist pattern.

Phase shifts may be obtained in a number of ways. For example, one process known as attenuated phase shifting (AttPSM) utilizes a mask that includes a layer of non-opaque material that causes light passing through the non-opaque material to change in phase compared to light passing through transparent parts of the mask. In addition, the non-opaque material can adjust the amount (intensity/magnitude) of light transmitted through the non-opaque material compared to the amount of light transmitted through transparent portions of the mask.

Another technique is known as alternating phase shift, where the transparent mask material (e.g., quartz or SiO₂ substrate) is sized (e.g., etched) to have regions of different depths or thicknesses. The depths are selected to cause a desired relative phase difference in light passing through the regions of different depths/thicknesses. The resulting mask is referred to as an “alternating phase shift mask” or “alternating phase shifting mask” (AltPSM). AttPSM and AltPSMs are referred to herein as “APSM.” The descriptions provided herein refer to AttPSMs; however, embodiments described herein are applicable to AltPSMs as well. The portion of the AltPSM having the thicker depth is referred to as the 0° phase portion, while the portion of the AltPSM having the lesser depth is referred to as the 180° phase portion. The depth difference allows the light to travel half of the wavelength in the transparent material, generating a phase difference of 180° between 0° and 180° portions. In some implementations, a patterned phase shifting material or absorber layer is located above the portions of the transparent mask substrate that has not been etched to different depths. The patterned phase shifting material is a material that affects the phase of the light passing through the phase shifting material such that the phase of the light passing through the phase shifting material is shifted relative to the phase of the light that does not pass through the phase shifting material, e.g., passes only through the transparent mask substrate material without passing through the phase shifting material. The phase shifting material can also reduce the amount of light transmitted through the phase shifting material relative to the amount of incident light that passes through portions of the mask not covered by the phase shifting material.

AttPSMs are not without their drawbacks. For example, when EUV radiation is incident on an AttPSM at a certain angle, reflection from the mask are potentially subjected to a shadowing effect or a mask induced imaging aberrations at the wafer these types of effects are sometimes referred to as mask 3D effects (M3D). Mask 3D effects may result, among other things, in reducing the contrast of aerial images and also the quality of resulting photoresist profiles.

In EUV lithography, to avoid overlap of incident light and reflected light, the EUV mask is illuminated with obliquely incident light that is tilted at a 6-degree angle relative to the axis perpendicular to the mask plane. The oblique incident EUV light is reflected by a reflective multilayer or absorbed by an absorber layer. On that occasion, if the absorber layer is thick, shadows are formed around the absorber lines that can make the absorber shapes to appear wider. The mask shadowing effects, also known as mask 3D (M3D) effects, can result in unwanted feature-size dependent focus and pattern placement shifts. The mask 3D effects become worse as the technology node advances, accordingly, the absorber thickness has to be reduced as much as possible to minimize the impact of mask 3D effects.

Newly manufactured APSMs may include defects or defects may form in APSMs that have been used for an extended period of time. Such defects may be the result of the materials, e.g., chromium based materials used in the absorber layer, that form a part of the APSM or a combination of the materials used to form the APSM and the conditions the APSM is subjected to during extended periods of use. Defects in features of an APSM that include chromium based materials can be repaired using a chromium based material. Repair of such defects can be a costly and time consuming process. In addition, it has been observed that an APSM with repaired defects may not perform as well, e.g., is not as effective at reducing M3D effects, as a defect free APSM. APSMs with absorber layers in accordance with embodiments of the present disclosure address some of these shortcomings.

In embodiments of the present disclosure, APSM structures and methods of producing such APSM structures are described. APSM structures in accordance with embodiments described herein include a patterned absorber layer which includes at least two different materials, e.g., a first material and a second material. In some embodiments, the patterned absorber layer has a thickness of about 20-100 nanometers. In some embodiments, the first material has an EUV refractive index (n) between 0.855-0.890 and an EUV extinction coefficient (k) between 0.035-0.075. In some embodiments, the second material has an EUV refractive index between 0.920-0.970 and an EUV extinction coefficient between 0-0.035. In some embodiments the first material and the second material are in separate layers, e.g., two separate layer or multiple, alternating, separate layers. In other embodiments the first material and the second material are combined to form an alloy in a single layer. APSM structures including absorber layer formed in accordance with embodiments disclosed herein are effective in reducing mask 3D effects that can result in unwanted feature size dependent focus and pattern placement shifts.

The following description relates to a mask fabrication process which includes two steps, a mask blank fabrication process and a mask fabrication process. During the mask blank fabrication process, a mask blank is formed by depositing suitable layers (e.g., multiple reflective layers) on a suitable substrate. The mask blank is patterned during the mask fabrication process to form a mask having a design of a layer of an IC device.

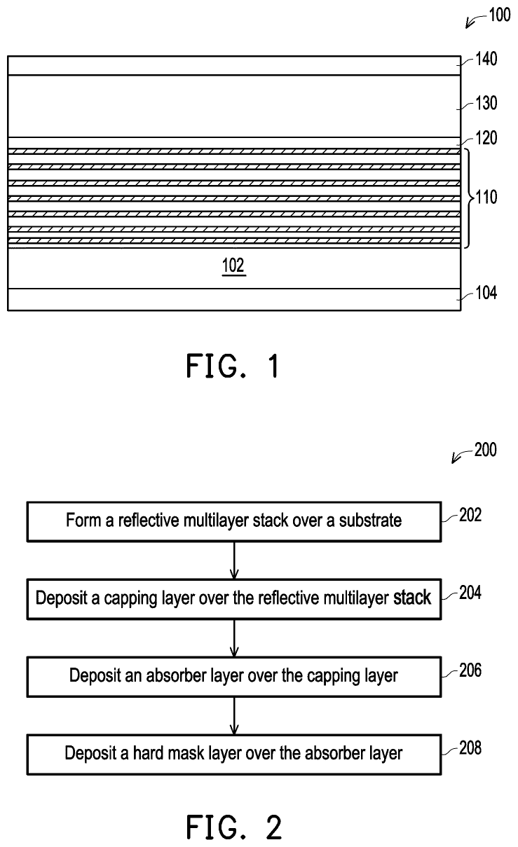

FIG. 1 is a cross-sectional view of an EUV mask blank 100, in accordance with a first embodiment of the present disclosure.

Referring to FIG. 1, the EUV mask blank 100 includes a substrate 102, a reflective multilayer stack 110 over a front surface of the substrate 102, a capping layer 120 over the reflective multilayer stack 110, an absorber layer 130 over the capping layer 120, and a hard mask layer 140 over the absorber layer 130. The EUV mask blank 100 further includes a conductive layer 104 over a back surface of the substrate 102 opposite the front surface. The absorber layer 130 includes a first material and a second material, wherein the first material has an EUV refractive index (n) between 0.855-0.890 and an EUV extinction coefficient (k) between 0.035-0.075 and wherein the second material has an EUV refractive index (n) between 0.920-0.970 and an EUV extinction coefficient (k) between 0-0.035. Further details of the first material, second material and their arrangement in multiple layers or as an alloy are described below in more detail.

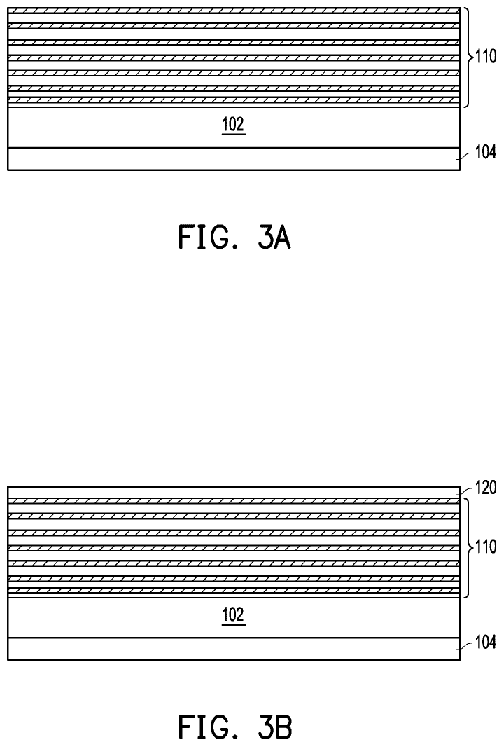

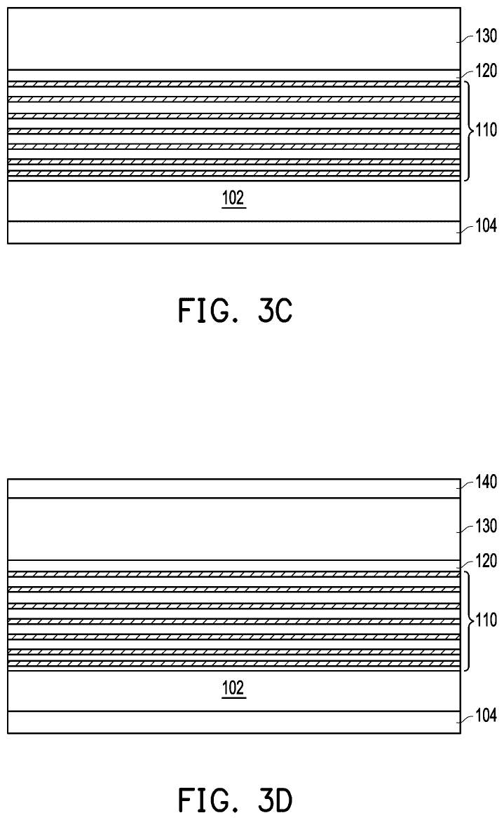

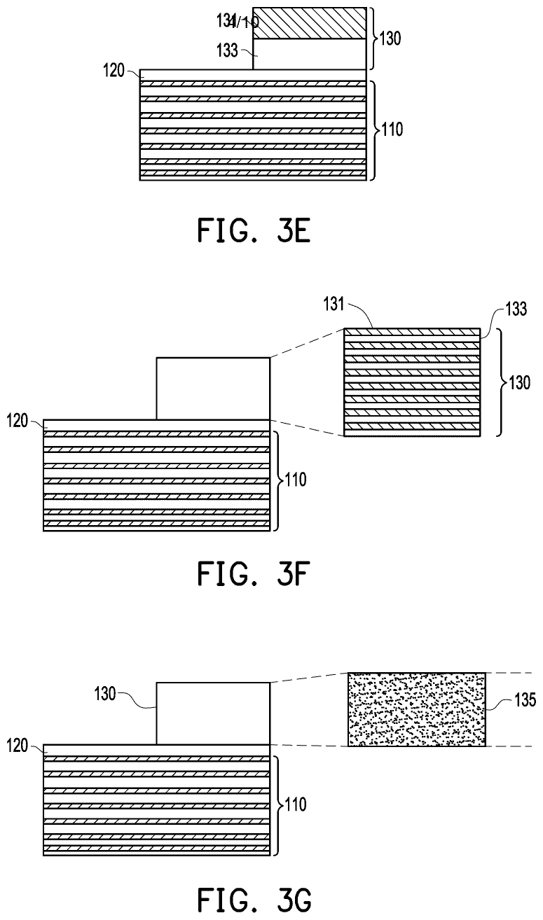

FIG. 2 is a flowchart of a method 200 for fabricating an EUV mask blank, for example, EUV mask blank 100, in accordance with some embodiments. FIG. 3A through FIG. 3D are cross-sectional views of the EUV mask blank 100 at various stages of the fabrication process, in accordance with some embodiments. The method 200 is discussed in detail below, with reference to the EUV mask blank 100. In some embodiments, additional operations are performed before, during, and/or after the method 200, or some of the operations described are replaced and/or eliminated. In some embodiments, some of the features described below are replaced or eliminated. One of ordinary skill in the art would understand that although some embodiments are discussed with operations performed in a particular order, these operations may be performed in another logical order.

Referring to FIGS. 2 and 3A, the method 200 includes operation 202, in which a reflective multilayer stack 110 is formed over a substrate 102, in accordance with some embodiments. FIG. 3A is a cross-sectional view of an initial structure of an EUV mask blank 100 after forming the reflective multilayer stack 110 over the substrate 102, in accordance with some embodiments.

Referring to FIG. 3A, the initial structure of the EUV mask blank 100 includes a substrate 102 made of glass, silicon, quartz, or other low thermal expansion materials. The low thermal expansion material helps to minimize image distortion due to mask heating during use of the EUV mask blank 100. In some embodiments, the substrate 102 includes fused silica, fused quartz, calcium fluoride, silicon carbide, black diamond, or titanium oxide doped silicon oxide (SiO₂/TiO₂). In some embodiments, the substrate 102 has a thickness ranging from about 1 mm to about 7 mm. If the thickness of the substrate 102 is too small, a risk of breakage or warping of the EUV mask blank 100 increases, in some instances. On the other hand, if the thickness of the substrate is too great, a weight of the EUV mask blank 100 is needlessly increased, in some instances.

In some embodiments, a conductive layer 104 is disposed on a back surface of the substrate 102. In some embodiments, the conductive layer 104 is in direct contact with the back surface of the substrate 102. The conductive layer 104 is adapted to provide for electrostatically coupling of the EUV mask blank 100 to an electrostatic mask chuck (not shown) during fabrication of the EUV mask blank 100. In some embodiments, the conductive layer 104 includes chromium nitride (CrN) or tantalum boride (TaB). In some embodiments, the conductive layer 104 is formed by a deposition process such as, for example, chemical vapor deposition (CVD), plasma-enhanced chemical vapor deposition (PECVD), or physical vapor deposition (PVD). The thickness of the conductive layer 104 is controlled such that the conductive layer 104 is optically transparent. In other embodiments a conductive layer 104 is not disposed on a back surface of the substrate 102.

The reflective multilayer stack 110 is disposed over a front surface of the substrate 102 opposite the back surface. In some embodiments, the reflective multilayer stack 110 is in directly contact with the front surface of the substrate 102. The reflective multilayer stack 110 provides a high reflectivity to the EUV light. In some embodiments, the reflective multilayer stack 110 is configured to achieve about 60% to about 75% reflectivity at the peak EUV illumination wavelength, e.g., the EUV illumination at 13.5 nm. Specifically, when the EUV light is applied at an incident angle of 4-7° to the surface of the reflective multilayer stack 110 a desired reflectivity of light is achieved. For example, when the incident angle is 6°, the maximum reflectivity of light in the vicinity of a wavelength of 13.5 nm is about 60%, about 62%, about 65%, about 68%, about 70%, about 72%, or about 75%.

In some embodiments, the reflective multilayer stack 110 includes alternatively stacked layers of a high refractive index material and a low refractive index material. A material having a high refractive index has a tendency to scatter EUV light on the one hand, and a material having a low refractive index has a tendency to transmit EUV light on the other hand. Pairing these two type materials together provides a resonant reflectivity. In some embodiments, the reflective multilayer stack 110 includes alternatively stacked molybdenum (Mo) layers and silicon (Si) layers. In some embodiments, the reflective multilayer stack 110 includes alternatively stacked Mo and Si layers with a Si layer being the topmost layer. In some embodiments, a Mo layer is in direct contact with the front surface of the substrate 102. In other some embodiments, a Si layer is in direct contact with the front surface of the substrate 102. Alternatively, the reflective multilayer stack 110 includes alternatively stacked layers of Mo and beryllium (Be).

The thickness of each layer in the reflective multilayer stack 110 depends on the EUV wavelength and the incident angle of the EUV light. The thickness of alternating layers in the reflective multilayer stack 110 is tuned to maximize the constructive interference of the EUV light reflected at each interface and to minimize the overall absorption of the EUV light. In some embodiments, the reflective multilayer stack 110 includes from 20 to 60 pairs of alternating Mo layers and Si layers. Each Mo and Si layer pair may have a thickness ranging from about 2 nm to about 7 nm, with a total thickness ranging from about 100 nm to about 300 nm.

In some embodiments, each layer in the reflective multilayer stack 110 is deposited over the substrate 102 and underlying layer using ion beam deposition (IBD) or DC magnetron sputtering. The deposition method used helps to ensure that the thickness uniformity of the reflective multilayer stack 110 is better than about 0.85 across the substrate 102. For example, to form a Mo/Si reflective multilayer stack 110, a Mo layer is deposited using a Mo target as the sputtering target and an argon (Ar) gas (having a gas pressure of from 1.3×10⁻² Pa to 2.7×10⁻² Pa) as the sputtering gas with an ion acceleration voltage of from 300 V to 1,500 V at a deposition rate of from 0.03 to 0.30 nm/sec and then a Si layer is deposited using a Si target as the sputtering target and an Ar gas (having a gas pressure of 1.3×10⁻² Pa to 2.7×10⁻² Pa) as the sputtering gas, with an ion acceleration voltage of from 300 V to 1,500 V at a deposition rate of from 0.03 to 0.30 nm/sec. By stacking Si layers and Mo layers in 20 to 60 cycles, each of the cycles comprising the above steps, the Mo/Si reflective multilayer stack is deposited.

Referring to FIGS. 2 and 3B, the method 200 proceeds to operation 204, in which a capping layer 120 is deposited over the reflective multilayer stack 110, in accordance with some embodiments. FIG. 3B is a cross-sectional view of the structure of FIG. 3A after depositing the capping layer 120 over the reflective multilayer stack 110, in accordance with some embodiments.

Referring to FIG. 3B, the capping layer 120 is disposed over the topmost surface of the reflective multilayer stack 110. The capping layer 120 helps to protect the reflective multilayer stack 110 from oxidation and any chemical etchants to which the reflective multilayer stack 110 may be exposed during subsequent mask blank and mask fabrication processes.

In some embodiments, the capping layer 120 includes a material that resists oxidation and corrosion, and has a low chemical reactivity with common atmospheric gas species such as oxygen, nitrogen, and water vapor. In some embodiments, the capping layer 120 includes a transition metal such as, for example, ruthenium (Ru), iridium (Ir), rhodium (Rh), platinum (Pt), palladium (Pd), osmium (Os), rhenium (Re), vanadium (V), tantalum (Ta), hafnium (Hf), tungsten (W), molybdenum (Mo), zirconium (Zr), manganese (Mn), technetium (Tc), or alloys thereof.

In some embodiments, the capping layer 120 is formed using a deposition process such as, for example, IBD, CVD, PECVD, PVD, or atomic layer deposition (ALD). The deposition of the capping layer 120 is often carried out at a relatively low temperature, for example, less than 150° C., to prevent inter-diffusion of the reflective multilayer stack 110. In instances where a Ru layer is to be formed as the capping layer 120 using IBD, the deposition may be carried out in an Ar atmosphere by using a Ru target as the sputtering target.

Referring to FIGS. 2 and 3C, the method 200 proceeds to operation 206, in which an absorber layer 130 is deposited or formed over the capping layer 120, in accordance with some embodiments. FIG. 3C is a cross-sectional view of the structure of FIG. 3B after depositing the absorber layer 130 over the capping layer 120, in accordance with some embodiments.

The absorber layer 130 is usable for absorbing radiation projected onto the EUV mask. The absorber layer 130 includes a combination of at least two different absorber materials. In some embodiments, the at least two different absorber materials include a first absorber material having an extinction coefficient k in the EUV wavelength range that is higher than an extinction coefficient in the EUV wavelength range of a second absorber material making up the absorber layer 130, while having a refractive index n in the EUV wavelength range lower than a refractive index n in the EUV wavelength range of the second material. In some embodiments, the absorber layer 130 includes a first absorber material and a second absorber material having the foregoing extinction coefficient k and refractive index n characteristics for an EUV wavelength of 13.5 nm. In some embodiments, the extinction coefficient k in the EUV wavelength range of the first material is between 0.035-0.075 and the extinction coefficient k in the EUV wavelength range of the second material is between 0-0.035. In some embodiments, the refractive index n in the EUV wavelength range of the first material of the absorber layer 130 is between 0.855-0.890 and the refractive index n in the EUV wavelength range of the second material of the absorber layer is between 0.920-0.970.

In some embodiments, the absorber layer 130 includes a first material and a second material which when combined in the manners described in more detail below, shift a phase of the EUV radiation reflected (R′) from a surface of a patterned absorber layer 130 by 1.05π to 1.65π compared to the phase of the EUV radiation reflected (R) from a surface of the capping layer 120. By deploying absorber layer materials in accordance with embodiments of the present disclosure, mask 3D effects caused by EUV phase distortion can be reduced. In accordance with some embodiments, reflectance by a patterned absorber layer 130 of EUV radiation incident on the patterned absorber layer is 1-15% of reflectance by a capping layer 120 of EUV radiation incident on the capping layer. As used herein, reflectance refers to the amount of electromagnetic radiation reflected from a surface or optical element. Reflectance can be represented as a ratio of reflected electromagnetic energy and incident electromagnetic energy. As a result, the focus shifts and pattern placement errors resulting from mask 3D effects can be reduced, while the normalized image log-slope (NILS) can be increased.

In some embodiments, the first material is a second row transition metal, such as yttrium (Y), zirconium (Zr), niobium (Nb), molybdenum (Mo), technetium (Tc), ruthenium (Ru), rhodium (Rh), palladium (Pd), silver (Ag) or cadmium (Cd). This series of transition metals involves the filling of 4d-orbitals. In some embodiments, the first material is a second row transition metal selected from group IVB (niobium), VB (molybdenum), VIIB (ruthenium) or VIIIB (palladium).

In some embodiments, the second material is a first row transition metal, such as scandium (Sc), titanium (Ti), vanadium (V), chromium (Cr), manganese (Mn), iron (Fe), cobalt (Co), nickel (Ni), copper (Cu) or zinc (Zn), or a second row transition metal, such as yttrium (Y), zirconium (Zr), niobium (Nb), molybdenum (Mo), technetium (Tc), ruthenium (Ru), rhodium (Rh), palladium (Pd), silver (Ag) or cadmium (Cd), or a third row transition metal, such as hafnium (Hf), tantalum (Ta), tungsten (W), rhenium (Rh), osmium (Os), iridium (Ir), platinum (Pt), gold (Au) or mercury (Hg). In some embodiments, the second material is not a first row transition metal, second row transition metal or third row transition metal. For example, second material is indium (In), tin (Sn), tellurium (Te), bismuth (Bi) or lead (Pb).

In some embodiments of the present disclosure, the first material includes one or more second row transition metal selected from niobium (Nb), molybdenum (Mo), ruthenium (Ru) and palladium (Pd) and the second material includes one or more transition metals selected from titanium (Ti), vanadium (V), chromium (Cr), iron (Fe), cobalt (Co), nickel (Ni), copper (Cu), zinc (Zn), hafnium (Hf), tantalum (Ta), tungsten (W), iridium (Ir), platinum (Pt) and gold (Au).

In some embodiments of the present disclosure, the first material includes technetium (Tc) and the second material includes one or more of scandium (Sc), yttrium (Y), zirconium (Zr), palladium (Pd), silver (Ag), cadmium (Cd), indium (In), tin (Sn), tellurium (Te), rhenium (Re), mercury (Hg) or lead (Pb).

The first material and the second material of the absorber layer 130 can be deployed in a number of different fashions. For example, referring to FIG. 3E, the absorber layer 130 includes a Layer A 131 over a Layer B 133. In some embodiments, Layer A 131 includes the first material and Layer B 133 includes the second material. In other embodiments, Layer A 131 includes the second material and Layer B 133 includes the first material. In some embodiments, Layer A 131 or Layer B 133 or both include a combination of two or more of the elements, e.g., RuTa or RuPt, useful as the first material or two or more of the elements useful as the second material.

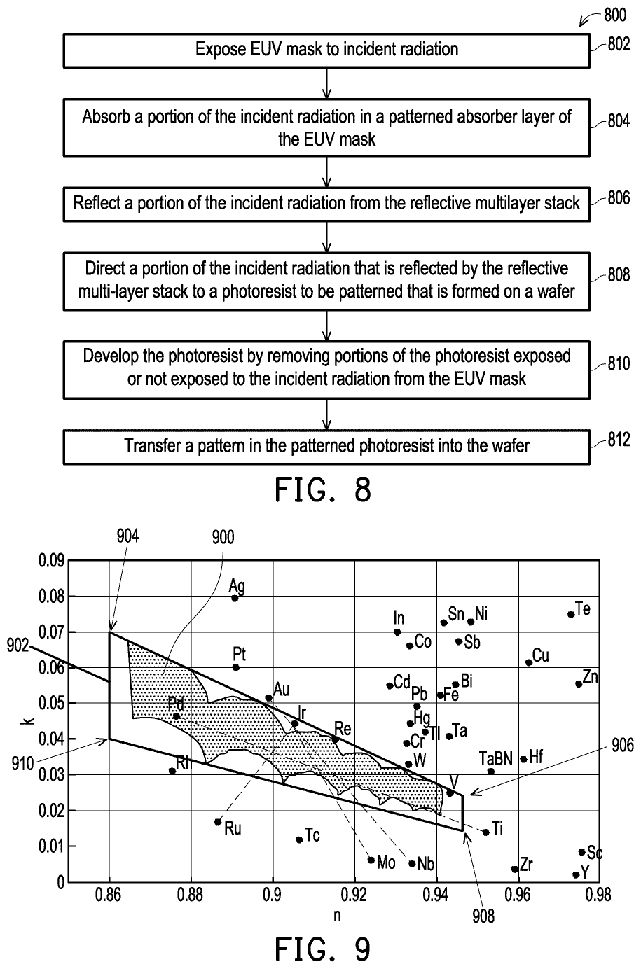

In some embodiments, the absorber layer 130 including Layer A and Layer B has a total thickness between 20-100 nanometers. In other embodiments Layer A and Layer B have a combined thickness of between 30-65 nanometers. In some embodiments, the thickness of Layer B is between 1-75% of the thickness of Layer A. In some embodiments, the thickness of Layer A is between 10 nanometers and 90 nanometers and the thickness of Layer B is between 90 nanometers and 10 nanometers. When absorber layer 130, Layer A and Layer B have thicknesses within the foregoing ranges, combination of Layer A and Layer B may fall within the green zone 900 of FIG. 9 described below and the absorber layer provides a desired level of phase shifting and a desired level of reflectivity. When absorber layer 130, Layer A and Layer B have thicknesses outside the foregoing ranges, combination of the materials of Layer A and Layer B may not fall within green zone 900 and the absorber layer may not provide a desired level of phase shifting or a desired level of reflectivity. Embodiments in accordance with the present disclosure are not limited to the foregoing thicknesses of Layer A and Layer B, for example, Layer A can have a thickness that falls outside the foregoing range and Layer B can have a thickness that falls outside the foregoing range. In some embodiments, the mass of the second material in the absorber layer is between 1% and 80% of the overall mass of the absorber layer. In some embodiments, the mass of the first material in the absorber layer is greater than 20% and less than 99% of the overall mass of the absorber layer.

In other embodiments illustrated in FIG. 3F, absorber layer 130 includes a plurality of alternating layers of the first material 131 and layers of the second material 133. In the embodiment illustrated in FIG. 3F, eight layers of the first material 131 and eight layers of the second material 133 are illustrated; however, embodiments in accordance with the present disclosure are not limited to eight layers of the first material 131 and eight layers of the second material 133. In other embodiments, greater than eight layers of the first material or the second material can be provided. In the embodiment illustrated in FIG. 3F, the uppermost layer is a layer of the first material; however, in other embodiments, the uppermost layer can be a layer of the second material. In the embodiment illustrated in FIG. 3F, the lowermost layer is a layer of the second material; however, in other embodiments, the lowermost layer can be a layer of the first material. The thickness of the individual layers of the first material and the second material can vary. For example, the thickness of each layer of the first material and the second material is between 0.5 nm to 1.5 nm. In other embodiments, the thickness of each layer of the first material and the second material is less than 0.5 nm or greater than 1.5 nm. In some embodiments, the thickness of the layer of first material is unequal to the thickness of adjacent layers of the second material. In some embodiments, the absorber layer 130 including the multiple layers of the first material and the second material has a total thickness between 20-100 nanometers. In other embodiments absorber layer 130 of FIG. 3F has a thickness of between 30-65 nanometers. In some embodiments, the combined thickness of the multiple layers of the second material is between 1-75% of the combined thickness of the multiple layers of the first material. In some embodiments, the combined thickness of the individual layers of the first material is between 10 nanometers and 90 nanometers and the combined thickness of the individual layers of the second material is between 90 nanometers and 10 nanometers. When absorber layer 130, and the layers of the first material 131 and the layers of the second material 133 have thicknesses within the foregoing ranges, the combination of the first material and the second material falls within the green zone 900 in FIG. 9 described below and the absorber layer provides a desired level of phase shifting and a desired level of reflectivity. When absorber layer 130, and the layers of the first material 131 and the layers of the second material 133 have thicknesses that fall outside the foregoing ranges, the combination of the first material and the second material does not fall within green zone 900 and the absorber layer may not provide a desired level of phase shifting or a desired level of reflectivity. Embodiments in accordance with the present disclosure are not limited to the foregoing combined thicknesses of the layers of the first material and the layers of the second material, for example, the combined thickness of the layers of the first material can fall outside the foregoing range and the combined thickness of the layers of the second material can fall outside the foregoing range. In some embodiments of the arrangement of FIG. 3F, the total mass of the second material in the absorber layer is greater than 1% and less than 80% of the overall mass of the absorber layer. In some embodiments, the total mass of the first material in the absorber layer is greater than 20% and less than 99% of the overall mass of the absorber layer.

In another embodiment, the absorber layer 130 is formed as a single layer of an alloy 135 of the first material and the second material. An alloy is a substance composed of two or more metals or of a metal and a non-metal intimately united usually by being fused together and dissolving each other when molten. FIG. 3G illustrates an example of such type of an embodiment of the present disclosure. In some embodiments of the embodiment of FIG. 3G, the absorber layer 130 including an alloy of the first material and the second material has a total thickness between 20-100 nanometers. In other embodiments, absorber layer 130 has a combined thickness of between 30-65 nanometers. Embodiments in accordance with the present disclosure are not limited to the foregoing thicknesses, for example, absorber layer of FIG. 3G can have a thickness that falls outside the foregoing range. In some embodiments, the mass of the second material in the absorber layer is greater than 1% and less than 80% of the overall mass of the absorber layer. In some embodiments, the mass of the first material in the absorber layer is greater than 20% and less than 99% of the overall mass of the absorber layer. In accordance with some embodiments of FIG. 3G, the atomic ratio of the first material to the second material of the absorber layer 130 is between 0.5:1 and 1.5:1. When atomic ratio of the first material to the second material of the absorber layer 130 fall within the foregoing range, the combination of the first material and the second material falls within the green zone 900 of FIG. 9 described below and the absorber layer provides a desired level of phase shifting and a desired level of reflectivity. When the atomic ratio of the first material to the second material of the absorber layer 130 falls outside the foregoing range, the combination of the first material and the second material of the absorber layer may not fall within green zone 900 and may not provide a desired level of phase shifting and/or level of reflectivity. Embodiments of FIG. 3G in accordance with the present disclosure are not limited to an atomic ratio of the first material to the second material of the absorber layer 130 within the foregoing range. For example, the atomic ratio of the first material to the second material of an absorber layer in accordance with FIG. 3G can fall above or below the foregoing range.

In accordance with embodiments of the present disclosure, exemplary combinations of the first material and the second material are listed in Tables 1-5 below. Combinations of the first material and the second material satisfying the criteria listed in Tables 1-5 provides a combination of first material and second material that fall within green zone 900 in FIG. 9 described below. Combinations of the first material and the second material falling outside the criteria listed in Tables 1-5 below result in combinations of the first material and the second material that fall outside the green zone 900.

TABLE 1
Ru First Material

| | | | Second Material |
|---|---|---|---|
| | | Total | Thickness % of |
| First | Second | Thickness | First Material |
| Material | Material | (nm) | Thickness |
| Ru | Hf | 50-54 | 44-53 |
| Ru | W | 44-49 | 52-70 |
| Ru | Ta | 44-49 | 40-57 |
| Ru | Zn | 46-49 | 35-38 |
| Ru | Cr | 43-48 | 50-64 |
| Ru | Cu | 40-44 | 29-32 |
| Ru | Fe | 40-43 | 30-36 |
| Ru | Sb | 39-43 | 20-30 |
| Ru | Ni | 39-42 | 20-30 |
| Ru | Co | 39-42 | 30-37 |
| Ru | Ir | 35-37 | 42-67 |
| Ru | Pt | 35-37 | 40-59 |

TABLE 2
Pd First Material

| | | | Second Material |
|---|---|---|---|
| | | Total | Thickness % of |
| First | Second | Thickness | First Material |
| Material | Material | (nm) | Thickness |
| Pd | V | 31-50 | 2-63 |
| Pd | Ti | 31-54 | 2-70 |
| Pd | B | 31-54 | 2-56 |
| Pd | Zr | 31-48 | 2-48 |
| Pd | RuTa | 31-50 | 0-100 |

TABLE 3
Mo First Material

| | | | Second Material |
|---|---|---|---|
| | | Total | Thickness % of |
| First | Second | Thickness | First Material |
| Material | Material | (nm) | Thickness |
| Mo | Au | 42-44 | 51-70 |
| Mo | Pt | 39-42 | 40-43 |
| Mo | Ir | 38-42 | 52-70 |
| Mo | Pd | 31-36 | 70-98 |

TABLE 4
Nb First Material

| | | | Second Material |
|---|---|---|---|
| | | Total | Thickness % of |
| First | Second | Thickness | First Material |
| Material | Material | (nm) | Thickness |
| Nb | Au | 43-48 | 45-68 |
| Nb | Pt | 43-48 | 33-52 |
| Nb | Ir | 38-43 | 51-70 |
| Nb | Pd | 31-36 | 70-90 |

TABLE 5
RuPt First Material

| | | | Second Material |
|---|---|---|---|
| | | Total | Thickness % of |
| First | Second | Thickness | First Material |
| Material | Material | (nm) | Thickness |
| RuPt | V | 37-50 | 2-58 |
| RuPt | Ti | 37-54 | 2-68 |
| RuPt | B | 37-54 | 2-52 |
| RuPt | Zr | 37-48 | 2-44 |

FIG. 9 is a graph of extinction coefficient k and index of refraction n for first materials and second materials useful as materials for an absorber layer or as materials for use to repair a defect in an absorber layer in accordance with some embodiments of the present disclosure. The plot of FIG. 9 includes a “green zone” 900 identified by shading. The green zone 900 falls within a polygon 902 in the plot of FIG. 9 which includes four corners 904, 906, 908, and 910. The four corners correspond to specific coordinates corresponding to index of refraction n and extinction coefficient k coordinates (n, k) in FIG. 9. In the embodiment of FIG. 9, such four coordinates are (0.86, 0.07) 904, (0.945, 0.025) 906, (0.945, 0.015) 908 and (0.86, 0.04) 910. As explained below in more detail, green zone 900 is used to identify a combination of a first material and a second material that provides an absorber layer that satisfies APSM criteria of an index of refraction between 0.860-0.945, an extinction coefficient of 0.070-0.015 and a thickness of 30-65 nm. In some embodiments, first material and second material are chosen such that a line connecting the two materials in FIG. 9 passes through at least a portion of the polygon 902 (e.g., through the green zone 900). For example, in FIG. 9 a line between first material ruthenium (Ru) and second material iridium (Ir) passes through a portion of green zone 900. Similarly, a line between molybdenum (Mo) and iridium (Ir), a line between palladium (Pd) and titanium (Ti) or a line between niobium (Nb) and gold (Au) passes through the green zone 900. Selecting a combination of a first material and a second material that meet the foregoing criteria provides an absorber layer for an APSM that exhibits satisfactory phase shift and reflectivity performance while effectively reducing M3D effects before being subjected to a repair process and after being subjected to a repair process. In addition, a combination of a first material and a second material that meet the foregoing criteria provides a material that is useful to repair defects in an APSM utilizing the first material and the second material in its absorber layer. Combinations of a first material and a second material that do not meet the foregoing criteria do not provide an absorber layer that exhibits satisfactory phase shift and reflectivity performance while effectively reducing M3D effects. Combinations of a first material and a second material that do not meet the foregoing criteria are not useful to repair defects in an APSM absorber layer.

The absorber layer 130 is formed by deposition techniques such as PVD, CVD, ALD, RF magnetron sputtering, DC magnetron sputtering, or IBD.

In embodiments of the present disclosure, by deploying the absorber layer materials as described above, the mask 3D effects caused by EUV phase distortion can be reduced. As a result, the best focus shifts and pattern placement error can be reduced, while the normalized image log-slope (NILS) can be increased.

Referring to FIGS. 2 and 3D, the method 200 proceeds to operation 208, in which a hard mask layer 140 is deposited over the absorber layer 130, in accordance with some embodiments. FIG. 3D is a cross-sectional view of the structure of FIG. 3C after depositing hard mask layer 140 over the absorber layer 130, in accordance with some embodiments.

Referring to FIG. 3D, the hard mask layer 140 is disposed over the absorber layer 130. The hard mask layer 140 possesses different etching characterizes from the absorber layer 130, and thereby serves as an etch stop layer to prevent damages to the absorber layer 130 during the photolithography process. In some embodiments, the hard mask layer 140 serves as an antireflection layer for reducing a reflection of the EUV radiation. In some embodiments, the hard mask layer 140 includes a dielectric material such as, for example, SiN, TaBO, TaO, CrO, or CrON.

In some embodiments, the hard mask layer 140 is formed using a deposition process such as, for example, CVD, PECVD, or PVD.

In some embodiments, the absorber layer surface includes a thin oxide layer which may be formed by oxidizing an upper surface of the absorber layer or deposited/formed on the upper surface of the absorber layer. Such thin oxide layer may be less than 10 nanometers thick.

Additionally, or alternatively, in some embodiments, a buffer layer (not shown) is formed on the capping layer 120 as an etch stop layer for patterning the absorber layer 130 and a sacrificial layer during a subsequent focused ion beam defect repair process for the absorber layer 130. The buffer layer may include silicon dioxide (SiO₂), silicon oxynitride (SiON), or other suitable materials.

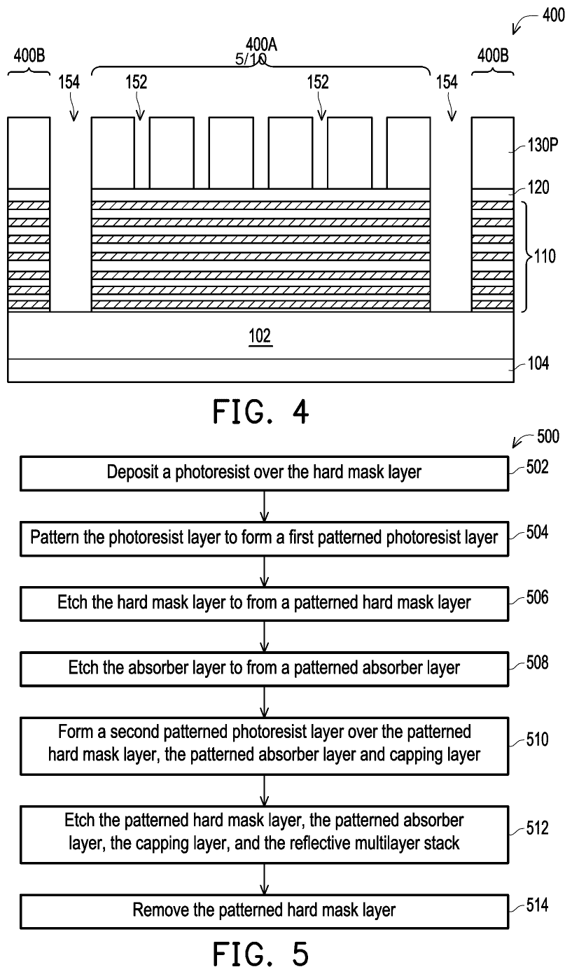

FIG. 4 is a cross-sectional view of an EUV mask 400 that is formed by patterning the absorber layer 130 of the EUV mask blank 100, in accordance with a second embodiment of the present disclosure. Referring to FIG. 4, the EUV mask 400 includes a substrate 102, a reflective multilayer stack 110 over a front surface of the substrate 102, a capping layer 120 over the reflective multilayer stack 110, and a patterned absorber layer 130P over the capping layer 120. The EUV mask 400 further includes a conductive layer 104 over a back surface of the substrate 102 opposite the front surface.

The patterned absorber layer 130P contain a pattern of openings 152 that correspond to circuit patterns to be formed on a semiconductor wafer. The pattern of openings 152 is located in a pattern region 400A of the EUV mask 400, exposing a surface of the capping layer 120. The pattern region 400A is surrounded by a peripheral region 400B of the EUV mask 400. The peripheral region 400B corresponds to a non-patterned region of the EUV mask 400 that is not used in an exposing process during IC fabrication. In some embodiments, the pattern region 400A of EUV mask 400 is located at a central region of the substrate 102, and the peripheral region 400B is located at an edge portion of the substrate 102. The pattern region 400A is separated from the peripheral region 400B by trenches 154. The trenches 154 extend through the patterned absorber layer 130P, the capping layer 120, and the reflective multilayer stack 110, exposing the front surface of the substrate 102.

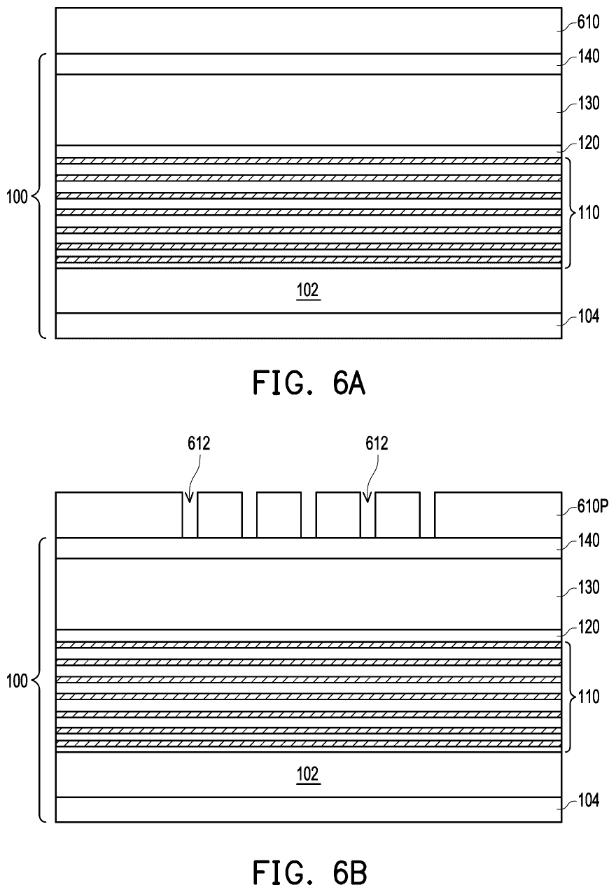

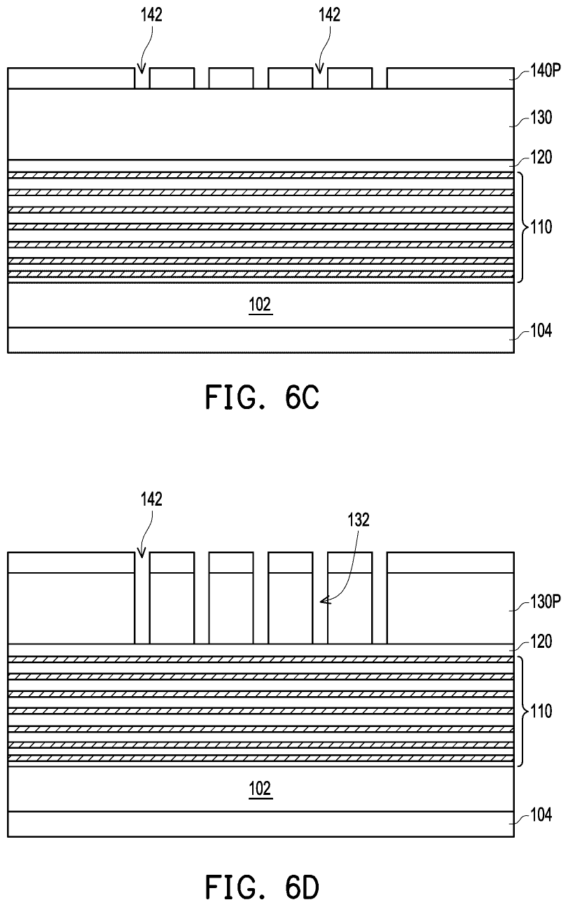

FIG. 5 is a flowchart of a method 500 for fabricating an EUV mask, for example, EUV mask 400, in accordance with some embodiments. FIG. 6A through FIG. 6G are cross-sectional views of the EUV mask 400 at various stages of the fabrication process, in accordance with some embodiments. The method 500 is discussed in detail below, with reference to the EUV mask 400. In some embodiments, additional operations are performed before, during, and/or after the method 500, or some of the operations described are replaced and/or eliminated. In some embodiments, some of the features described below are replaced or eliminated. One of ordinary skill in the art would understand that although some embodiments are discussed with operations performed in a particular order, these operations may be performed in another logical order.

Referring to FIGS. 5 and 6A, the method 500 includes operation 502, in which a photoresist layer 610 is deposited over the hard mask layer 140, in accordance with some embodiments. FIG. 6A is a cross-sectional view of a structure after depositing the photoresist layer 610 over the hard mask layer 140, in accordance with some embodiments.

Referring to FIG. 6A, the photoresist layer 610 is disposed over the topmost surface of the EUV mask blank 100, i.e., the hard mask layer 140. The photoresist layer 610 includes a photosensitive material operable to be patterned by radiation. In some embodiments, the photoresist layer 610 includes a positive-tone photoresist material, and a negative-tone photoresist material or a hybrid-tone photoresist material. In some embodiments, the photoresist layer 610 is applied to the surface of the hard mask layer 140, for example, by spin coating.

Referring to FIGS. 5 and 6B, the method 500 proceeds to operation 504, in which the photoresist layer 610 is lithographically patterned to form a patterned photoresist layer 610P, in accordance with some embodiments. FIG. 6B is a cross-sectional view of the structure of FIG. 6A after lithographically patterning the photoresist layer 610 to form the patterned photoresist layer 610P, in accordance with some embodiments.

Referring to FIG. 6B, the photoresist layer 610 is patterned by first subjecting the photoresist layer 610 to a pattern of irradiation. Next, the exposed or unexposed portions of the photoresist layer 610 are removed depending on whether a positive-tone or negative-tone resist is used in the photoresist layer 610 with a resist developer, thereby forming the patterned photoresist layer 610P having a pattern of openings 612 formed therein. The openings 612 expose portions of the hard mask layer 140. The openings 612 are located in the pattern region 400A and correspond to locations where the pattern of openings 152 are present in the EUV mask 400 (FIG. 4).

Referring to FIGS. 5 and 6C, the method 500 proceeds to operation 506, in which the hard mask layer 140 is etched using the patterned photoresist layer 610P as an etch mask to form a patterned hard mask layer 140P, in accordance with some embodiments. FIG. 6C is a cross-sectional view of the structure of FIG. 6B after etching the hard mask layer 140 to form the patterned hard mask layer 140P, in accordance with some embodiments.

Referring to FIG. 6C, portions of the hard mask layer 140 that are exposed by the openings 612 are etched to form openings 142 extending through the hard mask layer 140. The openings 142 expose portions of the underlying absorber layer 130. In some embodiments, the hard mask layer 140 is etched using an anisotropic etch. In some embodiments, the anisotropic etch is a dry etch such as, for example, reactive ion etch (RIE), a wet etch, or a combination thereof. The etch removes the material providing the hard mask layer 140 selective to the material providing the absorber layer 130. The remaining portions of the hard mask layer 140 constitute the patterned hard mask layer 140P. If not completely consumed during the etching of the hard mask layer 140, after etching the hard mask layer 140, the patterned photoresist layer 610P is removed from the surfaces of the patterned hard mask layer 140P, for example, using wet stripping or plasma ashing.

Referring to FIGS. 5 and 6D, the method 500 proceeds to operation 508, in which the absorber layer 130 is etched using the patterned hard mask layer 140P as an etch mask to form a patterned absorber layer 130P, in accordance with some embodiments. FIG. 6D is a cross-sectional view of the structure of FIG. 6C after etching the absorber layer 130 to form the patterned absorber layer 130P, in accordance with some embodiments.

Referring to FIG. 6D, portions of the absorber layer 130 that are exposed by the openings 142 are etched to form openings 132 extending through the absorber layer 130. The openings 132 expose portions of the underlying capping layer 120. The openings 132 in the patterned absorber layer 130P define the pattern of openings 152 in the EUV mask 400. In some embodiments, the absorber layer 130 is etched using an anisotropic etching process. In some embodiments, the anisotropic etch is a dry etch such as, for example, RIE, a wet etch, or a combination thereof that removes the material providing the absorber layer 130 selective to the material providing the underlying capping layer 120. For example, in some embodiments, the absorber layer 130 is dry etched with a gas that contains chlorine, such as Cl₂ or BCl₃, or with a gas that contains fluorine, such as NF₃. Argon (Ar) may be used as a carrier gas. In some embodiments, oxygen (O₂) may also be included as the carrier gas. The etch rate and the etch selectivity depend on the etchant gas, etchant flow rate, power, pressure, and substrate temperature. After etching, the remaining portions of the absorber layer 130 constitute the patterned absorber layer 130P.

Referring to FIGS. 5 and 6E, the method 500 proceeds to operation 510, in which a patterned photoresist layer 620P comprising a pattern of openings 622 is formed over the patterned hard mask layer 140P and the capping layer 120, in accordance with some embodiments. FIG. 6E is a cross-sectional view of the structure of FIG. 6D after forming the patterned photoresist layer 620P comprising openings 622 over the patterned hard mask layer 140P and the capping layer 120, in accordance with some embodiments.

Referring to FIG. 6E, the openings 622 expose portions of the patterned hard mask layer 140P at the periphery of the patterned absorber layer 130P. The openings 622 correspond to the trenches 154 in the peripheral region 400B of the EUV mask 400 (FIG. 4). To form the patterned photoresist layer 620P, a photoresist layer (not shown) is applied over the patterned hard mask layer 140P and the capping layer 120. The photoresist layer fills the openings 142 within the patterned hard mask layer 140P and the openings 132 within the patterned absorber layer 130P. In some embodiments, the photoresist layer includes a positive-tone photoresist material, a negative-tone photoresist material, or a hybrid-tone photoresist material. In some embodiments, the photoresist layer includes a same material as the photoresist layer 610 described above in FIG. 6A. In some embodiments, the photoresist layer includes a different material from the photoresist layer 610. In some embodiments, the photoresist layer is formed, for example, by spin coating. The photoresist layer is subsequently patterned by exposing the photoresist layer to a pattern of radiation, and removing the exposed or unexposed portions of the photoresist layer using a resist developer depending on whether a positive or negative resist is used. The remaining portions of the photoresist layer constitute the patterned photoresist layer 620P.

Referring to FIGS. 5 and 6F, the method 500 proceeds to operation 512, in which the patterned hard mask layer 140P, the patterned absorber layer 130P, the capping layer 120, and the reflective multilayer stack 110 are etched using the patterned photoresist layer 620P as an etch mask to form trenches 154 in the peripheral region 400B of the substrate 102, in accordance with some embodiments. FIG. 6F is a cross-sectional view of the structure of FIG. 6E after etching the patterned hard mask layer 140P, the patterned absorber layer 130P, the capping layer 120, and the reflective multilayer stack 110, to form the trenches 154 in the peripheral region 400B of the substrate 102, in accordance with some embodiments.

Referring to FIG. 6F, the trenches 154 extend through the patterned hard mask layer 140P, the patterned absorber layer 130P, the capping layer 120, and the reflective multilayer stack 110 to expose the surface of the substrate 102. The trenches 154 surround the pattern region 400A of the EUV mask 400, separating the pattern region 400A from the peripheral region 400B.

In some embodiments, the patterned hard mask layer 140P, the patterned absorber layer 130P, the capping layer 120, and the reflective multilayer stack 110 are etched using a single anisotropic etching process. The anisotropic etch can be a dry etch such as, for example, RIE, a wet etch, or a combination thereof that removes materials of the respective patterned hard mask layer 140P, patterned absorber layer 130P, capping layer 120, and reflective multilayer stack 110, selective to the material providing the substrate 102. In some embodiments, the patterned hard mask layer 140P, the patterned absorber layer 130P, the capping layer 120, and the reflective multilayer stack 110 are etched using multiple distinct anisotropic etching processes. Each anisotropic etch can be a dry etch such as, for example, RIE, a wet etch, or a combination thereof.

Subsequently, the patterned photoresist layer 620P is removed from the pattern region 400A and the peripheral region 400B of the substrate 102, for example, by wet stripping or plasma ashing. The removal of the patterned photoresist layer 620P from the openings 142 in the patterned hard mask layer 140P and the openings 132 in the patterned absorber layer 130P re-exposes the surfaces of the capping layer 120 in the pattern region 400A.

Referring to FIGS. 5 and 6G, the method 500 proceeds to operation 514, in which the patterned hard mask layer 140P is removed, in accordance with some embodiments. FIG. 6G is a cross-sectional view of the structure of FIG. 6F after removing patterned hard mask layer 140P, in accordance with some embodiments.

Referring to FIG. 6G, the removal of the patterned hard mask layer 140P exposes the surfaces of the patterned absorber layer 130P. In some embodiments, the patterned hard mask layer 140P is removed by an etching process which can be an anisotropic etch or an isotropic etch. In some embodiments, the etch can be a dry etch such as RIE or a wet chemical etch that selectively removes the patterned hard mask layer 140P without removing the remaining patterned absorber layer 130P, the capping layer 120, the reflective multilayer stack 110, and the substrate 102.

After removal of the patterned hard mask layer 140P, the EUV mask 400 may be cleaned to remove any contaminants therefrom. In some embodiments, the EUV mask 400 is cleaned by submerging the EUV mask 400 into an ammonium hydroxide (NH₄OH) solution. In some embodiments, the EUV mask 400 is cleaned by submerging the EUV mask 400 into a diluted hydrofluoric acid (HF) solution.

The EUV mask 400 is subsequently radiated with, for example, an UV light with a wavelength of 193 nm, for inspection of any defects in the patterned region 400A. The foreign matters may be detected from diffusely reflected light. If defects are detected, the EUV mask 400 is further cleaned using suitable cleaning processes.

The patterned absorber layer 130P includes a first material and a second material that provide a combination of individual refractive indices, EUV extinction coefficients and thickness properties which allow for forming an absorber layer which reduces mask 3D effects. As a result, a pattern on the EUV mask 400 can be projected precisely onto a semiconductor wafer.

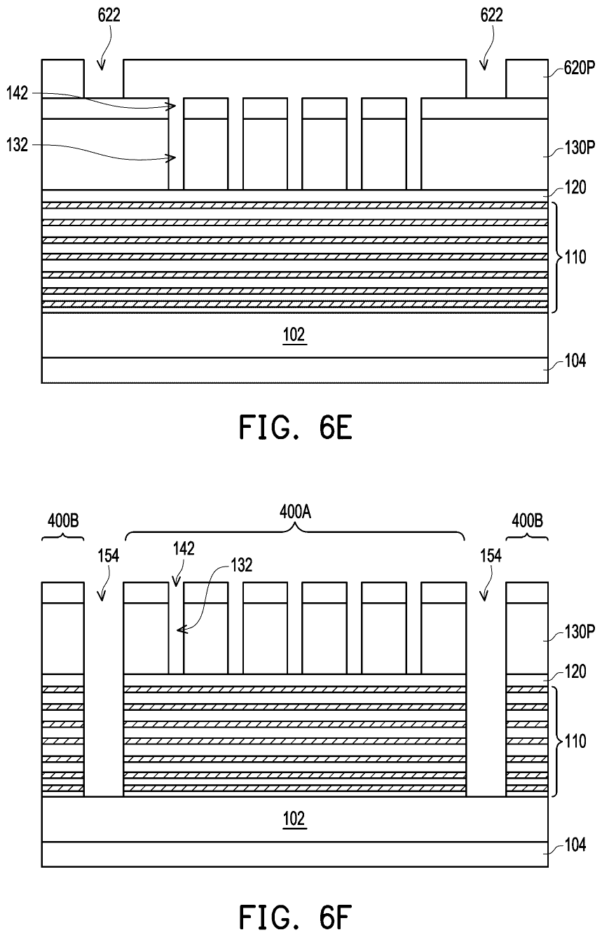

FIG. 7 is a schematic diagram of a lithography system 700, in accordance with some embodiments of the present disclosure. The lithography system 700 may also be referred to herein as a “scanner” that is operable to perform lithography exposing processes with respective radiation sources and exposure modes.

In some embodiments, the lithography system 700 includes a high-brightness light source 702, an illuminator 704, a mask stage 706, a photomask (i.e., EUV mask 400), a projection optics module 710, and a substrate stage 712. In some embodiments, the lithography system may include additional components that are not illustrated in FIG. 7. In further embodiments, one or more of the high-brightness light source 702, the illuminator 704, the mask stage 706, the projection optics module 710, and the substrate stage 712 may be omitted from the lithography system 700 or may be integrated into combined components.

The high-brightness light source 702 may be configured to emit radiation having wavelengths in the range of approximately 1 nanometer (nm) to 250 nm. In some embodiments, the high-brightness light source 702 generates EUV light with a wavelength centered at approximately 13.5 nanometers; accordingly, the high-brightness light source 702 may also be referred to as an “EUV light source.”

In embodiments where the lithography system 700 is an EUV lithography system, the illuminator 704 comprises various reflective optical components, such as a single mirror or a mirror system comprising multiple mirrors. The illuminator 704 may direct light from the high-brightness light source 702 onto the mask stage 706, and more particularly onto the EUV mask 400 that is secured onto the mask stage 706.

The mask stage 706 may be configured to secure the EUV mask 400. In some examples, the mask stage 706 may include an electrostatic chuck (e-chuck) to secure the EUV mask 400. This is because the gas molecules absorb EUV light, and the lithography system 700 for EUV lithography patterning is maintained in a vacuum environment to minimize EUV intensity loss.

In some examples, a pellicle 714 may be positioned over the EUV mask 400, e.g., between the EUV mask 400 and the substrate stage 712. The pellicle 714 may protect the EUV mask 400 from particles and may keep the particles out of focus, so that the particles do not produce an image (which may cause defects on a wafer during the lithography process).

The projection optics module 710 may be configured for imaging the pattern of the EUV mask 400 onto a semiconductor wafer 716 secured on the substrate stage 712. In some embodiments, the projection optics module 710 comprises reflective optics for the EUV lithography system. The light directed from the EUV mask 400, carrying the image of the pattern defined on the EUV mask 400, may be collected by the projection optics module 710. The illuminator 704 and the projection optics module 710 may be collectively referred to as an “optical module” of the lithography system 700.

In some embodiments, the semiconductor wafer 716 may be a bulk semiconductor wafer. For instance, the semiconductor wafer 716 may comprise a silicon wafer. The semiconductor wafer 716 may include silicon or another elementary semiconductor material, such as germanium. In some embodiments, the semiconductor wafer 716 may include a compound semiconductor. The compound semiconductor may include gallium arsenide, silicon carbide, indium arsenide, indium phosphide, another suitable material, or a combination thereof. In some embodiments, the semiconductor wafer 716 includes a silicon-on-insulator (SOI) substrate. The SOI substrate may be fabricated using a separation by implantation of oxygen (SIMOX) process, a wafer bonding process, another applicable process, or a combination thereof. In some embodiments, the semiconductor wafer 716 comprises an undoped substrate. However, in other embodiments, the semiconductor wafer 716 comprises a doped substrate, such as a p-type substrate or an n-type substrate.

In some embodiments, the semiconductor wafer 716 includes various doped regions (not shown) depending on the design requirements of the semiconductor device structure. The doped regions may include, for example, p-type wells and/or n-type wells. In some embodiments, the doped regions are doped with p-type dopants. For example, the doped regions may be doped with boron or boron fluoride. In other examples, the doped regions are doped with n-type dopants. For example, the doped regions may be doped with phosphor or arsenic. In some examples, some of the doped regions are p-doped and other doped regions are n-doped.

In some embodiments, an interconnection structure may be formed over the semiconductor wafer 716. The interconnection structure may include multiple interlayer dielectric layers, including dielectric layers. The interconnection structure may also include multiple conductive features formed in the interlayer dielectric layers. The conductive features may include conductive lines, conductive vias, and/or conductive contacts.

In some embodiments, various device elements are formed in the semiconductor wafer 716. Examples of the various device elements may include transistors (e.g., metal oxide semiconductor field effect transistors (MOSFETs), complementary metal oxide semiconductor (CMOS) transistors, bipolar junction transistors (BJTs), high-voltage transistors, high-frequency transistors, p-channel and/or n-channel field effect transistors (PFETs and/or NFETs)), diodes, or other suitable elements. Various processes may be used to form the various device elements, including deposition, etching, implantation, photolithography, annealing, and/or other applicable processes.

The device elements may be interconnected through the interconnection structure over the semiconductor wafer 716 to form integrated circuit devices. The integrated circuit devices may include logic devices, memory devices (e.g., static random access memory (SRAM) devices), radio frequency (RF) devices, input/output (I/O) devices, system-on-chip (SoC) devices, image sensor devices, other applicable devices, or a combination thereof.

In some embodiments, the semiconductor wafer 716 may be coated with a photoresist that is sensitive to EUV light. Various components including those described above may be integrated together and may be operable to perform lithography exposing processes.

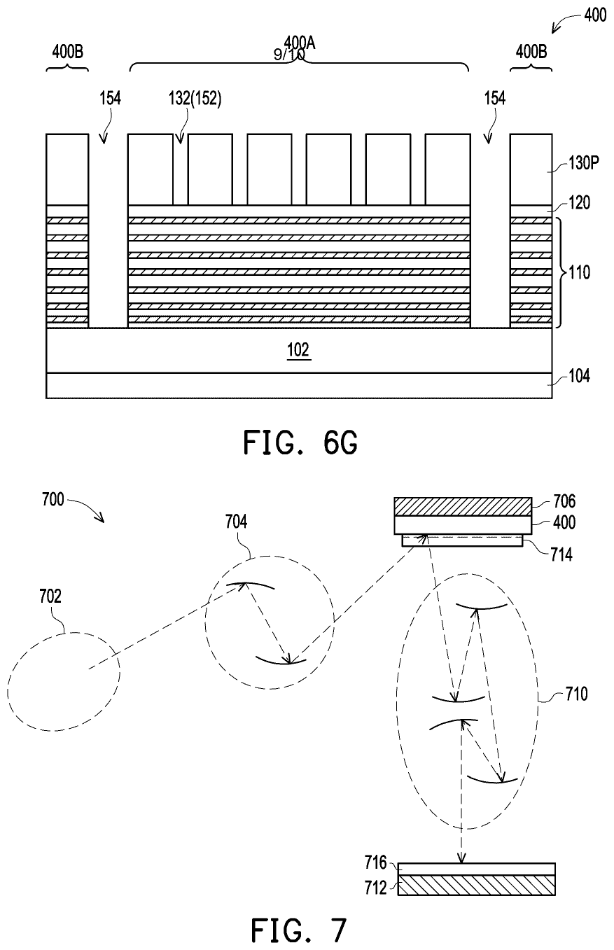

FIG. 8 illustrates a method 800 of using an EUV mask, in accordance with embodiments of the present disclosure. Method 800 includes step 802 of exposing an EUV mask to an incident radiation, e.g., EUV radiation. An example of an EUV mask useful in step 802 includes the EUV mask 400 described above. At step 804, a portion of the incident radiation is absorbed by a patterned absorber layer 130P of the EUV mask 400. At step 806, a portion of the incident radiation is reflected from the reflective multilayer stack 110. A portion of the incident radiation that is reflected by the reflective multilayer stack 110 is directed to a photoresist that is disposed on a semiconductor wafer in step 808. After the photoresist to be patterned has been exposed to the radiation reflected from the EUV mask 400, portions of the photoresist exposed or not exposed to the radiation reflected from the EUV mask 400 are removed at step 810. At step 812, a pattern in the patterned photoresist is transferred into the semiconductor wafer.

One aspect of this description relates to an extreme ultraviolet mask. The EUV mask includes a substrate, a reflective multilayer stack on the substrate, a capping layer on the reflective multilayer stack and a patterned absorber layer on the capping layer. The patterned absorber layer includes a first material and a second material, wherein the first material has an EUV refractive index (n) between 0.855-0.890 and an EUV extinction coefficient (k) between 0.035-0.075 and wherein the second material has an EUV refractive index (n) between 0.920-0.970 and an EUV extinction coefficient (k) between 0-0.035.

Another aspect of this description relates to relates to a method of patterning a photoresist using an EUV mask. The method includes exposing the EUV mask to an incident radiation. The EUV mask includes a reflective multilayer stack on a substrate, a capping layer on the reflective multilayer stack and a patterned absorber layer on the capping layer. The patterned absorber layer has a thickness between 20-100 nanometers and includes a first material and a second material. The first material has an EUV refractive index (n) in the EUV wavelength range between 0.855-0.890 and an EUV extinction coefficient (k) in the EUV wavelength range between 0.035-0.075. The second material has an EUV refractive index (n) in the EUV wavelength range between 0.920-0.970 and an EUV extinction coefficient (k) in the EUV wavelength range between 0-0.035. The method further includes reflecting from the patterned absorber layer, EUV radiation incident on the patterned absorber layer and reflecting from the capping layer, EUV radiation incident on the capping layer. The method includes shifting a phase of the EUV radiation reflected from the patterned absorber layer by 1.05π to 1.65π compared to the phase of the EUV radiation reflected from the capping layer.

Still another aspect of this description relates to an extreme ultraviolet (EUV) mask. The EUV mask includes a substrate, a reflective multilayer stack on the substrate, a capping layer on the reflective multilayer stack, and a patterned absorber layer on the capping layer. The patterned absorber layer includes a first material and a second material, wherein the first material has an EUV refractive index (n) between 0.855-0.890 and an EUV extinction coefficient (k) between 0.035-0.075 and wherein the second material has an EUV refractive index (n) between 0.920-0.970 and an EUV extinction coefficient (k) between 0-0.035.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
exposing an extreme ultraviolet (EUV) mask to an incident radiation, the EUV mask comprising:
a substrate;
a reflective multilayer stack on the substrate;
a capping layer on the reflective multilayer stack; and
a patterned absorber layer having a thickness between 20-100 nanometers on the capping layer, wherein the patterned absorber layer includes a first material and a second material, wherein the first material has an EUV refractive index (n) between 0.855-0.890 and an EUV extinction coefficient (k) between 0.035-0.075 and wherein the second material has an EUV refractive index (n) between 0.920-0.970 and an EUV extinction coefficient (k) between 0-0.035;
absorbing a portion of the incident radiation by the patterned absorber layer;
transmitting a portion of the incident radiation through the capping layer;
reflecting a portion of the incident radiation from the reflective multilayer stack; and
directing a portion of incident radiation that is reflected by the reflective multilayer stack to a semiconductor substrate to expose a photoresist layer disposed thereon.

2. The method of claim 1, wherein a weight % of the second material of the patterned absorber layer is between 1 to 80% of the combined weight of the first material and the second material.

3. The method of claim 1, wherein the first material includes one or more second row transition metals selected from yttrium (Y), zirconium (Zr), niobium (Nb), molybdenum (Mo), technetium (Tc), ruthenium (Ru), rhodium (Rh), palladium (Pd), silver (Ag) and cadmium (Cd).

4. The method of claim 3, wherein the first material includes palladium (Pd).

5. The method of claim 1, wherein the second material includes one or more first, second and third row transition metals selected from scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Rh), osmium (Os), iridium (Ir), platinum (Pt), gold (Au) and mercury (Hg).

6. The method of claim 5, wherein the second material comprises one or more transition metals selected from titanium (Ti), vanadium (V), hafnium (Hf), tungsten (W), molybdenum (Mo), niobium (Nb) and zirconium (Zr).

7. The method of claim 1, wherein the patterned absorber layer has a thickness between 30 and 65 nanometers.

8. The method of claim 1, wherein the patterned absorber layer includes a first layer of the first material and a second layer of the second material.

9. The method of claim 1, wherein the patterned absorber layer includes alternating first layers of the first material and second layers of the second material.

10. The method of claim 1, wherein the patterned absorber layer includes a single layer including an alloy of the first material and the second material.

11. The method of claim 1, further comprising developing the photoresist layer to form a patterned photoresist layer.

12. The method of claim 11, further comprising transferring a pattern in the patterned photoresist layer into the semiconductor substrate.

13. A method, comprising:
exposing an extreme ultraviolet (EUV) mask to an incident radiation, the EUV mask comprising:
a substrate;
a reflective multilayer stack on the substrate;
a capping layer on the reflective multilayer stack; and
a patterned absorber layer on the capping layer, the patterned absorber layer including a first layer of a first material and a second layer of a second material over the first layer, wherein the first material having an EUV refractive index (n) and an EUV extinction coefficient (k) and the second material having an EUV refractive index (n) and an EUV extinction coefficient (k), wherein, in a plot of EUV refractive index (n) vs EUV extinction coefficient (k) for the first material and the second material, a line between a first material coordinate defined by the EUV refractive index (n) and the EUV extinction coefficient (k) of the first material and a second material coordinate defined by the EUV refractive index (n) and the EUV extinction coefficient (k) of the second material passes through a polygon defined in the plot by four coordinates (n, k), the four coordinates being (0.860, 0.070), (0.945, 0.025), (0.945, 0.015) and (0.860, 0.040);
absorbing a portion of the incident radiation by the patterned absorber layer;
transmitting a portion of the incident radiation through the capping layer;
reflecting a portion of the incident radiation from the reflective multilayer stack;
directing a portion of incident radiation that is reflected by the reflective multilayer stack to a semiconductor substrate to expose a photoresist layer disposed thereon; and
developing the photoresist layer.

14. The method of claim 13, wherein the first material includes one or more second row transition metals selected from niobium (Nb), molybdenum (Mo), ruthenium (Ru), palladium (Pd) and technetium (Tc).

15. The method of claim 14, wherein the second material includes one or more transition metals selected from titanium (Ti), vanadium (V), chromium (Cr), iron (Fe), cobalt (Co), nickel (Ni), copper (Cu), zinc (Zn), hafnium (Hf), tantalum (Ta), tungsten (W), iridium (Ir), platinum (Pt) and gold (Au).

16. The method of claim 13, wherein the patterned absorber layer has a thickness in the range between 30-65 nanometers, wherein a thickness of the first layer is between 1-75% of a thickness of the second layer.

17. A method, comprising:
exposing an extreme ultraviolet (EUV) mask to an incident radiation, the EUV mask comprising:
a substrate;
a reflective multilayer stack on the substrate;
a capping layer on the reflective multilayer stack; and
a patterned absorber layer on the capping layer, the patterned absorber layer including alternating first layers of a first material and second layers of a second material different from the first material, wherein the first material includes one or more metals selected from niobium (Nb), molybdenum (Mo), ruthenium (Ru) and palladium (Pd) and the second material includes one or more metals selected from titanium (Ti), vanadium (V), chromium (Cr), iron (Fe), cobalt (Co), nickel (Ni), copper (Cu), zinc (Zn), hafnium (Hf), tantalum (Ta), tungsten (W), iridium (Ir), platinum (Pt), gold (Au), indium (In), tin (Sn) and bismuth (Bi);
absorbing a portion of the incident radiation by the patterned absorber layer;
transmitting a portion of the incident radiation through the capping layer;
reflecting a portion of the incident radiation from the reflective multilayer stack; and
directing a portion of incident radiation that is reflected by the reflective multilayer stack to a semiconductor substrate to expose a photoresist layer disposed thereon.

18. The method of claim 17, wherein the patterned absorbing layer has a thickness between 20-100 nm.

19. The method of claim 18, wherein a total thickness of the first layers is between 1-75% of a total thickness of the second layers.

20. The method of claim 17, wherein the first material includes ruthenium (Ru) and the second material includes one or more metals selected from hafnium (Hf), tungsten (W), tantalum (Ta), zinc (Zn), chromium (Cr), copper (Cu), iron (Fe), nickel (Ni), cobalt (Co), iridium (Ir) and platinum (Pt).
